(19) United States
(12) Patent Application Publication
(10) Pub. No.: US 2026/0259370 A1
(43) Pub. Date: Sep. 3, 2026

(54) SILICON NITRIDE CORE RIB WAVEGUIDES AND METHODS OF MANUFACTURING THE SAME

(71) Applicant: CORNING INCORPORATED, CORNING, NY (US)

(72) Inventors: Sukru Ekin Kocabas, Santa Clara, CA (US); Barry James Paddock, Horseheads, NY (US); Haitao Zhang, Ithaca, NY (US); Bin Zhu, Ithaca, NY (US)

(21) Appl. No.: 19/158,094

(22) PCT Filed: Feb. 27, 2024
(86) PCT No.: PCT/US2024/017371

§ 371 Date: Aug. 20, 2025

Related U.S. Application Data
(60) Provisional application No. 63/450,411, filed on Mar. 7, 2023.

(51) Int. Cl. G02B 6/122; G02B 6/12; G02B 6/132; G02B 6/134; G02B 6/136; H04B 10/70

(52) U.S. Cl. CPC G02B 6/1228; G02B 6/132; G02B 6/134; G02B 6/136; H04B 10/70; G02B 2006/12038; G02B 2006/1208; G02B 2006/12097; G02B 2006/12173

(57) ABSTRACT

A method of manufacturing a silicon nitride optical device includes depositing a silicon nitride film on a rare-earth doped transparent polycrystalline ceramic substrate, depositing an aluminum film on the silicon nitride film, and coating a photoresist layer on the aluminum film. The method then includes exposing the sample in a photolith using a rib waveguide photo mask, etching the aluminum film, and removing the photoresist layer. The method further includes etching the silicon nitride film to a depth, removing the aluminum film, and depositing a silicon dioxide (SiO₂) cladding on to the silicon nitride film and the rare-earth doped transparent polycrystalline ceramic substrate.

### CROSS-REFERENCE TO RELATED APPLICATIONS

This application claims the benefit of priority under 35 U.S.C. § 119 of U.S. Provisional Application Ser. No. 63/450,411 filed on Mar. 7, 2023, the content of which is relied upon and incorporated herein by reference in its entirety.

### FIELD

The present disclosure relates to rib waveguides and, more particularly, to silicon nitride rib waveguides deposited on rare-earth doped transparent ceramic substrates.

### TECHNICAL BACKGROUND

In optical quantum information processing, quantum memories are devices that enable the entanglement of photons and atoms and synchronize the quantum processing networks. Among studied quantum memory materials, rare-earth doped solids have attracted much attention because the 4f-4f transitions of rare earth ions are shielded by 5s and 5p orbitals, and thus they have long optical coherence lifetime.

Although research in this field has focused on single crystal materials, new research has revealed that polycrystalline ceramics can be used to replace single crystals. These optical waveguides based on rare-earth doped ceramics are highly desired platforms for optical quantum memories. Such waveguide structures can offer several advantages such as lower cost, high optical density, long interaction length, low insertion loss, and more robust and compact device packaging. Accordingly, methods of manufacturing rare-earth doped metal oxide ceramic waveguides that incorporate ease of patterning and etching may be desired.

### SUMMARY

According to a first aspect A1, a method of fabricating a rib waveguide comprises depositing a silicon nitride film on a rare-earth doped transparent polycrystalline ceramic substrate; depositing an aluminum film on the silicon nitride film; coating a photoresist on the aluminum film; exposing the photoresist using a rib waveguide photo mask; etching the aluminum film; removing the photoresist; etching the silicon nitride film to a depth; removing the aluminum film; and depositing a silicon dioxide (SiO2) cladding on to the silicon nitride film and the rare-earth doped transparent polycrystalline ceramic substrate.

A second aspect A2 incudes the method of fabricating a rib waveguide of the first aspect A1, wherein the rare-earth doped transparent polycrystalline ceramic substrate comprises yttrium oxide and an erbium dopant, or yttrium oxide and the erbium dopant mixed with one or a combination of the following dopants: lanthanum, scandium, and/or lutetium.

A third aspect A3 includes the method of fabricating a rib waveguide of the first aspect A1, further comprising an initial step of cleaning the rare-earth doped transparent polycrystalline ceramic substrate, wherein the initial step of cleaning comprises applying at least one of acetone, isopropyl alcohol, and oxygen (O₂) plasma.

A fourth aspect A4 includes the method of fabricating a rib waveguide of the first aspect A1, wherein the silicon nitride film has a pre-etching thickness from greater than or equal to 300 nm to less than or equal to 600 nm.

A fifth aspect A5 includes the method of fabricating a rib waveguide of the first aspect A1, wherein the aluminum film has a pre-etching thickness from greater than or equal to 5 nm to less than or equal to 50 nm.

A sixth aspect A6 includes the method of fabricating a rib waveguide of the first aspect A1, wherein the photoresist is removed by O₂ plasma.

A seventh aspect A7 includes the method of fabricating a rib waveguide of the first aspect A1, wherein the silicon nitride film is etched from 150 nm to 300 nm, forming the rib waveguide comprising a silicon nitride base having a thickness from 100 nm to 500 nm; and a silicon nitride core rib having a width from 1 μm to 20 μm and a taper angle from 85° to 90°.

An eighth aspect A8 includes the method of fabricating a rib waveguide of the first aspect A1, wherein the aluminum film is removed by reactive ion etching.

A ninth aspect A9 includes the method of fabricating a rib waveguide of the first aspect A1, wherein the SiO₂ cladding has a thickness from greater than or equal to 1 μm to less than or equal to 5 μm.

A tenth aspect A10 a rib waveguide may comprise a rare-earth doped transparent polycrystalline ceramic substrate having a substrate refractive n_{S}. The rib waveguide may further comprise a silicon nitride core disposed on the rare-earth doped transparent polycrystalline ceramic substrate, the silicon nitride core having a core rib refractive index n_{CR} and a cladding layer disposed on the silicon nitride core and the rare-earth doped transparent polycrystalline ceramic substrate, the cladding layer having a cladding refractive index n_{Cl}, wherein n_{CR}>n_{S}>n_{Cl}.

An eleventh aspect A11 includes the rib waveguide of the tenth aspect A10, wherein the rare-earth doped transparent polycrystalline ceramic substrate comprises yttrium oxide.

A twelfth aspect A12 includes the rib waveguide of the eleventh aspect A11, wherein the rare-earth doped transparent polycrystalline ceramic substrate comprises an erbium dopant, or the erbium dopant mixed with one or a combination of the following dopants: lanthanum, scandium, and/or lutetium.

A thirteenth aspect A13 includes the rib waveguide of the tenth aspect A10, wherein the silicon nitride core comprises: a silicon nitride base having a thickness from 100 nm to 500 nm and a silicon nitride core rib having a width from 1 μm to 20 μm and a taper angle from 85° to 90°.

A fourteenth aspect A14 includes the rib waveguide of the tenth aspect A10, wherein the rare-earth doped transparent polycrystalline ceramic has a thickness (t′) may be greater than or equal to 0.1 mm and less than or equal to 5 mm.

A fifteenth aspect A15 includes the rib waveguide of the tenth aspect A10, wherein the n_{CR} may be greater than or equal to 1.9 and less than or equal to 2.1.

A sixteenth aspect A16 includes the rib waveguide of the tenth aspect A10, wherein the n_{S} may be greater than or equal to 1.87 and less than or equal to 1.91.

A seventeenth aspect A17 includes the rib waveguide of the tenth aspect A10, wherein the n_{Cl} may be greater than or equal to 1.40 and less than or equal to 1.50.

An eighteenth aspect A18 includes the rib waveguide of the tenth aspect A10, wherein the cladding layer comprises silica-based glass.

A nineteenth aspect A19 includes a quantum memory system comprising an optical device comprising a silicon nitride core on a rare-earth doped polycrystalline ceramic substrate, a magnetic field generation unit, a storage photon generator, and one or more pump lasers, wherein: the optical device is positioned within a magnetic field of the magnetic field generation unit when the magnetic field generation unit generates the magnetic field; the one or more pump lasers are optically coupled to the optical device; the storage photon generator is optically coupled to the optical device and is structurally configured to output an entangled pair of storage photons comprising a first entangled storage photon entangled with a second entangled storage photon; and the optical device further comprises a cladding surrounding the silicon nitride core.

A twentieth aspect A20 includes a quantum memory system of the nineteenth aspect A19, wherein the rare-earth doped polycrystalline ceramic substrate comprises yttrium oxide.

A twenty-first aspect A21 includes a quantum memory system of the nineteenth aspect A19, wherein the rare-earth element dopant comprises an erbium dopant, or the erbium dopant mixed with one or a combination of the following dopants: lanthanum, scandium, and/or lutetium.

A twenty-second aspect A22 includes a quantum memory system of the nineteenth aspect A19, wherein the cladding surrounding the silicon nitride core comprises silica-based glass.

A twenty-third aspect A23 includes a quantum memory system of the nineteenth aspect A19, wherein the silicon nitride core comprises: a silicon nitride base having a thickness from 100 nm to 300 nm; and a silicon nitride core rib having a width from 1 μm to 20 μm and a taper angle from 85° to 90°.

Additional features and advantages of the rib waveguide and methods of manufacturing the same as described herein will be set forth in the detailed description which follows, and in part will be readily apparent to those skilled in the art from that description or recognized by practicing the embodiments described herein, including the detailed description which follows, the claims, as well as the appended drawings.

It is to be understood that both the foregoing general description and the following detailed description are merely exemplary, and are intended to provide an overview or framework to understanding the nature and character of the claimed subject matter. The accompanying drawings are included to provide a further understanding and are incorporated in and constitute a part of this specification. The drawings illustrate one or more embodiment(s), and together with the description, serve to explain principles and operation of the various embodiments.

### BRIEF DESCRIPTION OF THE SEVERAL VIEWS OF THE DRAWINGS

The following detailed description of specific embodiments of the present disclosure can be best understood when read in conjunction with the following drawings, in which:

FIG. 1 illustrates a cross section of a rib waveguide, according to one or more embodiments shown and described herein;

FIG. 2 graphically depicts the relationship between a dopant and the refractive index of a rib waveguide, according to one or more embodiments shown and described herein;

FIG. 3 graphically depicts the relationship between a wavelength and the refractive index of a rib waveguide, according to one or more embodiments shown and described herein;

FIG. 4 illustrates an isometric view of a silicon nitride optical device, according to one or more embodiments shown and described herein;

FIG. 5 depicts a flow diagram of an illustrative method for a steps of manufacturing a rib waveguide, according to one or more embodiments shown and described herein;

FIG. 6 illustrates each step in the method for manufacturing a rib waveguide, according to one or more embodiments shown and described herein;

FIG. 7 is a schematic illustration of a quantum memory system having an optical device comprising a rib waveguide, according to one or more embodiments shown and described herein;

FIG. 8 illustrates a schematic view of a rib waveguide design, according to one or more embodiments shown and described herein; and

FIG. 9 graphically depicts the light distribution of a simulated rib waveguide according to one or more embodiments shown and described herein.

### DETAILED DESCRIPTION

Reference will now be made in detail to exemplary embodiments which are illustrated in the accompanying drawings. Whenever possible, the same reference numerals will be used throughout the drawings to refer to the same or like parts. The components in the drawings are not necessarily to scale, emphasis instead being placed upon illustrating the principles of the exemplary embodiments. The disclosure should not be construed as limited to the embodiments set forth herein. Rather, these embodiments are provided so that this disclosure will be thorough and complete, and will fully convey the subject matter to those skilled in the art.

Additionally, any examples set forth in this specification are illustrative, but not limiting, and merely set forth embodiments of the subjected matter described herein. Other suitable modifications and adaptions of the variety of conditions and parameters normally encountered in the field, and which would be apparent to those skilled in the art, are within the spirit and scope of this disclosure.

Unless otherwise defined, all technical and scientific terms used herein have the same meaning as commonly understood by one of ordinary skill in the art. The terminology used in the disclosure herein is for describing particular embodiments only and is not intended to be limiting.

Ranges can be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

Directional terms as used herein-for example up, down, right, left, front, back, top, bottom-are made only with reference to the figures as drawn and are not intended to imply absolute orientation.

The term “and/or” shall also be interpreted to be inclusive (e.g., “x and/or y” means one or both x or y). In situations where “and/or” or “or” are used as a conjunction for a group of three or more items, the group should be interpreted to include one item alone, all the items together, or any combination or number of the items. Moreover, terms used in the specification and claims such as have, having, include, and including should be construed to be synonymous with the terms comprise and comprising Unless otherwise expressly stated, it is in no way intended that any method set forth herein be construed as requiring that its steps be performed in a specific order, nor that with any apparatus specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

As used herein, the singular forms “a,” “an” and “the” include plural referents unless the context clearly dictates otherwise. Thus, for example, reference to “a” component includes aspects having two or more such components, unless the context clearly indicates otherwise.

As utilized herein, “optional,” “optionally,” or the like are intended to mean that the subsequently described event or circumstance can or cannot occur, and that the description includes instances where the event or circumstance occurs and instances where it does not occur.

The term “coupled” means the joining of two members directly or indirectly to one another. Such joining may be stationary in nature or movable in nature. Such joining may be achieved with the two members or the two members and any additional intermediate members being integrally formed as a single unitary body with one another or with the two members or the two members and any additional intermediate member being attached to one another. Such joining may be permanent in nature or alternatively may be removable or releasable in nature.

The term “plasma enhanced chemical vapor deposition,” or “PECVD,” is a low temperature vacuum thin film deposition process that allows for application of coatings on surfaces at lower temperatures with less stress to the thin film interfaces.

The term “oxygen plasma cleaning” means any plasma treatment performed after introducing oxygen to the plasma chamber. Other gases in addition to oxygen may also be introduced into the plasma chamber.

As discussed hereinabove, rib waveguides are used in optical quantum information processing to facilitate the entanglement of photons and atoms and synchronize the quantum processing networks. Polycrystalline ceramics have been shown to have advantageous properties over conventional single crystal quantum memory materials, such as lower cost and ease of manufacturing into other devices. However, patterning waveguide structures directly in yttrium oxide (Y₂O₃) ceramics is challenging. This is because Y₂O₃ is difficult to directly etch, and it is difficult to make a smooth and straight angled etched sidewall. The grain and grain boundary structure in Y₂O₃ ceramics also significantly influences the etching uniformity.

Disclosed herein are rib waveguides and methods of manufacturing the same which mitigate the aforementioned problems. Specifically, this disclosure presents a method for fabricating rib waveguides on erbium (Er³⁺) doped transparent Y₂O₃ ceramics without directly etching the Y₂O₃. The refractive index of the erbium doped Y₂O₃ substrate can be tuned by adding co-dopants such as lanthanum. Silicon nitride is used as the waveguide core material. The refractive index of the silicon nitride can be tuned during deposition to achieve the desired optical characteristics in the waveguide. Additionally, reactive ion etching (RIE) of the silicon nitride allows for deep etching of the waveguide core material to obtain smooth and straight angle sidewalls.

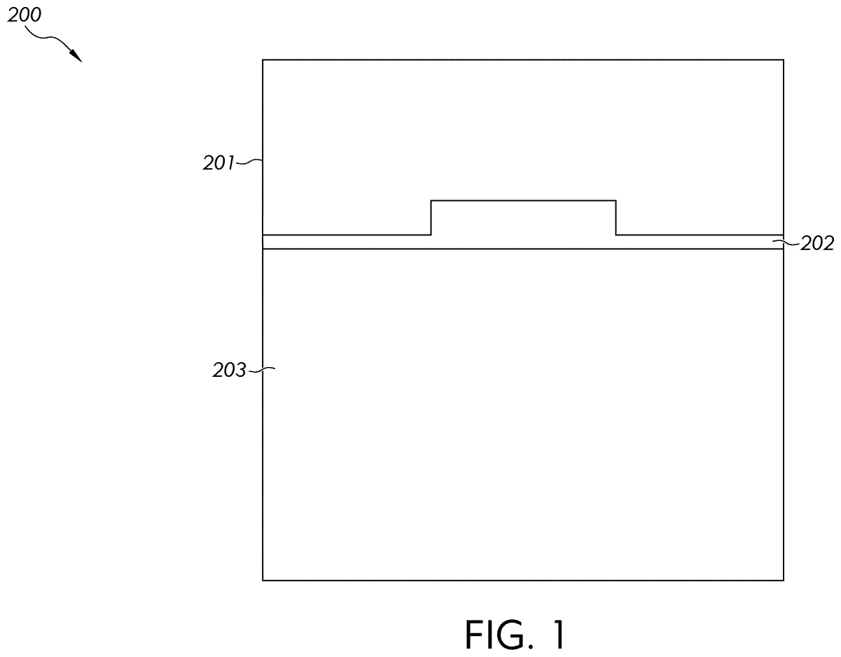

Now referring to FIG. 1, a side view of a rib waveguide 200 is schematically depicted according to one or more embodiments shown and described herein. The rib waveguide 200 comprises a rare-earth doped transparent polycrystalline ceramic substrate (hereinafter “polycrystalline ceramic substrate”) 203, a core 202 formed from silicon nitride (i.e., a silicon nitride core) positioned on the polycrystalline ceramic substrate 203, and a cladding layer 201 positioned on the core 202 such that the core 202 is disposed between the cladding layer 201 and the polycrystalline ceramic substrate 203. In the embodiments described herein, the polycrystalline ceramic substrate 203 has a substrate refractive index n_{S}. The core 202 has a core rib refractive index n_{CR}. In the embodiments described herein, n_{CR} is greater than n_{S} (i.e., n_{CR}>n_{S}). The cladding layer 201 has a cladding refractive index n_{Cl}. In embodiments, n_{Cl} is less than n_{CR} and n_{S} (i.e., n_{CR}>n_{S}>n_{Cl}).

In embodiments, the polycrystalline ceramic substrate 203 is formed from yttrium oxide (Y₂O₃). In embodiments described herein, the polycrystalline ceramic substrate 203 of the rib waveguide 200 is doped with at least one rare-earth element dopant that is uniformly distributed within a crystal lattice of the polycrystalline ceramic substrate 203. In embodiments, the polycrystalline ceramic substrate 203 may be doped with erbium. In embodiments, the polycrystalline ceramic substrate 203 may be doped with erbium in the range of 0.0005 wt % to 0.01 wt % based on the total weight of the polycrystalline ceramic substrate 203. For lower amounts of erbium, the optical signal may be too weak for a quantum process such that the substrate cannot be used to manufacture a waveguide. Additionally, if there is too much erbium in the substrate, the coherence time will be reduced, resulting in a substrate that is not suitable for waveguide manufacturing. For example, erbium may be present in the polycrystalline ceramic substrate 203 from 0.0005 wt % to 0.001 wt %, from 0.0005 wt % to 0.0015 wt %, from 0.0005 wt % to 0.002 wt %, from 0.0005 wt % to 0.0025 wt %, from 0.0005 wt % to 0.003 wt %, from 0.0005 wt % to 0.0035 wt %, from 0.0005 wt % to 0.004 wt %, from 0.0005 wt % to 0.0045 wt %, from 0.0005 wt % to 0.005 wt %, from 0.0005 wt % to 0.0055 wt %, from 0.0005 wt % to 0.006 wt %, from 0.0005 wt % to 0.0065 wt %, from 0.0005 wt % to 0.007 wt %, from 0.0005 wt % to 0.0075 wt %, from 0.0005 wt % to 0.008 wt %, from 0.0005 wt % to 0.0085 wt %, from 0.0005 wt % to 0.009 wt %, from 0.0005 wt % to 0.0095 wt %, from 0.0005 wt % to 0.01 wt %, from 0.002 wt % to 0.0025 wt %, from 0.002 wt % to 0.003 wt %, from 0.002 wt % to 0.0035 wt %, from 0.002 wt % to 0.004 wt %, from 0.002 wt % to 0.0045 wt %, from 0.002 wt % to 0.005 wt %, from 0.002 wt % to 0.0055 wt %, from 0.002 wt % to 0.002 wt %, from 0.002 wt % to 0.0065 wt %, from 0.002 wt % to 0.007 wt %, from 0.002 wt % to 0.0075 wt %, from 0.002 wt % to 0.008 wt %, from 0.002 wt % to 0.0085 wt %, from 0.002 wt % to 0.009 wt %, from 0.002 wt % to 0.0095 wt %, from 0.002 wt % to 0.01 wt %, from 0.004 wt % to 0.0045 wt %, from 0.004 wt % to 0.005 wt %, from 0.004 wt % to 0.0055 wt %, from 0.004 wt % to 0.006 wt %, from 0.004 wt % to 0.0065 wt %, from 0.004 wt % to 0.007 wt %, from 0.004 wt % to 0.0075 wt %, from 0.004 wt % to 0.008 wt %, from 0.004 wt % to 0.0085 wt %, from 0.004 wt % to 0.009 wt %, from 0.004 wt % to 0.0095 wt %, from 0.004 wt % to 0.01 wt %, from 0.006 wt % to 0.0065 wt %, from 0.006 wt % to 0.007 wt %, from 0.006 wt % to 0.0075 wt %, from 0.006 wt % to 0.008 wt %, from 0.006 wt % to 0.0085 wt %, from 0.006 wt % to 0.009 wt %, from 0.006 wt % to 0.0095 wt %, from 0.006 wt % to 0.01 wt %, from 0.008 wt % to 0.0085 wt %, from 0.008 wt % to 0.009 wt %, from 0.008 wt % to 0.0095 wt %, or even from 0.008 wt % to 0.01 wt %, or any and all endpoints formed by these subranges.

It is contemplated that the polycrystalline ceramic substrate 203 may be doped with other rare-earth elements such as europium, ytterbium, praseodymium, thulium, or holmium, which may be present in concentrations of about 0.0005 wt % to about 2 wt % based on the total weight of the polycrystalline ceramic substrate 203.

In some embodiments, at least one rare-earth metal co-dopant (e.g., lanthanum (La³⁺), lutetium (Lu³⁺), scandium (Sc³⁺)) or oxides thereof may be used as index modifiers to increase the refractive index of the polycrystalline ceramic substrate. Notably, these rare-earth metals increase the refractive index if the polycrystalline ceramic substrate 203 without influencing the coherence properties of the erbium-doped substrate. The rare-earth element co-dopant(s) may be included in a concentration from about 0.0005 wt % to about 20 wt % based on the total weight of the polycrystalline ceramic substrate 203. For these refractive index-modifying dopants, doping the substrate with too much may reduce the transparency of the polycrystalline ceramic substrate 203. For example, the rare-earth element co-dopant(s) may be present in the polycrystalline ceramic substrate 203 from 0.0005 wt % to 0.001 wt %, from 0.0005 wt % to 0.0015 wt %, from 0.0005 wt % to 0.002 wt %, from 0.0005 wt % to 0.0025 wt %, from 0.0005 wt % to 0.003 wt %, from 0.0005 wt % to 0.0035 wt %, from 0.0005 wt % to 0.004 wt %, from 0.0005 wt % to 0.0045 wt %, from 0.0005 wt % to 0.005 wt %, from 0.0005 wt % to 0.0055 wt %, from 0.0005 wt % to 0.006 wt %, from 0.0005 wt % to 0.0065 wt %, from 0.0005 wt % to 0.007 wt %, from 0.0005 wt % to 0.0075 wt %, from 0.0005 wt % to 0.008 wt %, from 0.0005 wt % to 0.0085 wt %, from 0.0005 wt % to 0.009 wt %, from 0.0005 wt % to 0.0095 wt %, from 0.0005 wt % to 0.01 wt %, from 0.01 wt % to 1.75 wt %, from 0.01 wt % to 1.50 wt %, from 0.01 wt % to 1.25 wt %, from 0.01 wt % to 1.00 wt %, from 0.01 wt % to 0.75 wt %, from 0.01 wt % to 0.50 wt %, from 0.01 wt % to 0.25 wt %, from 0.01 wt % to 0.1 wt %, from 0.1 wt % to 0.25 wt %, from 0.1 wt % to 0.5 wt %, from 0.1 wt % to 0.75 wt %, from 0.1 wt % to 1.00 wt %, from 1.00 wt % to 1.50 wt %, from 1.00 wt % to 2.00 wt %, from 1.00 wt % to 2.50 wt %, from 1.00 wt % to 3.50 wt %, from 1.00 wt % to 4.00 wt %, from 1.00 wt % to 4.50 wt %, from 1.00 wt % to 5.00 wt %, from 1.00 wt % to 5.50 wt %, from 1.00 wt % to 6.00 wt %, from 1.00 wt % to 6.50 wt %, from 1.00 wt % to 7.00 wt %, from 1.00 wt % to 7.50 wt %, from 1.00 wt % to 8.00 wt %, from 1.00 wt % to 8.50 wt %, from 1.00 wt % to 9.00 wt %, from 1.00 wt % to 9.50 wt %, from 1.00 wt % to 10.00 wt %, from 1.00 wt % to 10.50 wt %, from 1.00 wt % to 11.00 wt %, from 1.00 wt % to 11.50 wt %, from 1.00 wt % to 12.00 wt %, from 1.00 wt % to 12.50 wt %, from 1.00 wt % to 13.00 wt %, from 1.00 wt % to 13.50 wt %, from 1.00 wt % to 14.00 wt %, from 1.00 wt % to 14.50 wt %, from 1.00 wt % to 15.00 wt %, from 1.00 wt % to 15.50 wt %, from 1.00 wt % to 16.00 wt %, from 1.00 wt % to 16.50 wt %, from 1.00 wt % to 17.00 wt %, from 1.00 wt % to 17.50 wt %, from 1.00 wt % to 18.00 wt %, from 1.00 wt % to 18.50 wt %, from 1.00 wt % to 19.00 wt %, from 1.00 wt % to 19.50 wt %, from 1.00 wt % to 20.00 wt %, from 5.00 wt % to 5.50 wt %, from 5.00 wt % to 6.00 wt %, from 5.00 wt % to 6.50 wt %, from 5.00 wt % to 7.00 wt %, from 5.00 wt % to 7.50 wt %, from 5.00 wt % to 8.00 wt %, from 5.00 wt % to 8.50 wt %, from 5.00 wt % to 9.00 wt %, from 5.00 wt % to 9.50 wt %, from 5.00 wt % to 10.00 wt %, from 5.00 wt % to 10.50 wt %, from 5.00 wt % to 11.00 wt %, from 5.00 wt % to 11.50 wt %, from 5.00 wt % to 12.00 wt %, from 5.00 wt % to 12.50 wt %, from 5.00 wt % to 13.00 wt %, from 5.00 wt % to 13.50 wt %, from 5.00 wt % to 14.00 wt %, from 5.00 wt % to 14.50 wt %, from 5.00 wt % to 15.00 wt %, from 5.00 wt % to 15.50 wt %, from 5.00 wt % to 16.00 wt %, from 5.00 wt % to 16.50 wt %, from 5.00 wt % to 17.00 wt %, from 5.00 wt % to 17.50 wt %, from 5.00 wt % to 18.00 wt %, from 5.00 wt % to 18.50 wt %, from 5.00 wt % to 19.00 wt %, from 5.00 wt % to 19.50 wt %, from 5.00 wt % to 20.00 wt %, from 10.00 wt % to 10.50 wt %, from 10.00 wt % to 11.00 wt %, from 10.00 wt % to 11.50 wt %, from 10.00 wt % to 12.00 wt %, from 10.00 wt % to 12.50 wt %, from 10.00 wt % to 13.00 wt %, from 10.00 wt % to 13.50 wt %, from 10.00 wt % to 14.00 wt %, from 10.00 wt % to 14.50 wt %, from 10.00 wt % to 15.00 wt %, from 10.00 wt % to 15.50 wt %, from 10.00 wt % to 16.00 wt %, from 10.00 wt % to 16.50 wt %, from 10.00 wt % to 17.00 wt %, from 10.00 wt % to 17.50 wt %, from 10.00 wt % to 18.00 wt %, from 10.00 wt % to 18.50 wt %, from 10.00 wt % to 19.00 wt %, from 10.00 wt % to 19.50 wt %, from 10.00 wt % to 20.00 wt %, from 15.00 wt % to 15.50 wt %, from 15.00 wt % to 16.00 wt %, from 15.00 wt % to 16.50 wt %, from 15.00 wt % to 17.00 wt %, from 15.00 wt % to 17.50 wt %, from 15.00 wt % to 18.00 wt %, from 15.00 wt % to 18.50 wt %, from 15.00 wt % to 19.00 wt %, from 15.00 wt % to 19.50 wt %, or even from 15.00 wt % to 20.00 wt %, or any and all endpoints formed by these subranges.

As noted herein, the polycrystalline ceramic substrate 203 is a rare-earth doped substrate having a substrate refractive n_{S}. In embodiments, the substrate refractive n_{S} at 1550 nm may be greater than or equal to 1.87 and less than or equal to 1.91, greater than or equal to 1.875 and less than or equal to 1.895, or even greater than or equal to 1.877 and less than or equal to 1.885.

Polycrystalline ceramic substrates, such as rare earth doped Y₂O₃ transparent polycrystalline ceramic substrates may be fabricated according to previously developed methods by sintering rare earth doped Y₂O₃ nanoparticles as disclosed in U.S. Pat. Nos. 10,304,536 B2 and 10,553,280, which are hereby incorporated in their entirety.

In embodiments, the polycrystalline ceramic substrate may be prepared with a thickness of 0.1-5 mm and with diameter of up to 5 cm. For example, the polycrystalline ceramic substrate may have a thickness from 0.1 mm to 0.2 mm, from 0.1 mm to 0.4 mm, from 0.1 mm to 0.6 mm, from 0.1 mm to 0.8 mm, from 0.1 mm to 1.0 mm, from 0.1 mm to 1.2 mm, from 0.1 mm to 1.4 mm, from 0.1 mm to 1.6 mm, from 0.1 mm to 1.8 mm, from 0.1 mm to 2.0 mm, from 0.1 mm to 2.2 mm, from 0.1 mm to 2.4 mm, from 0.1 mm to 2.6 mm, from 0.1 mm to 2.8 mm, from 0.1 mm to 3.0 mm, from 0.1 mm to 3.2 mm, from 0.1 mm to 3.4 mm, from 0.1 mm to 3.6 mm, from 0.1 mm to 3.8 mm, from 0.1 mm to 4.0 mm, from 0.1 mm to 4.2 mm, from 0.1 mm to 4.4 mm, from 0.1 mm to 4.6 mm, from 0.1 mm to 4.8 mm, from 0.1 mm to 5.0 mm, from 1.0 mm to 1.2 mm, from 1.0 mm to 1.4 mm, from 1.0 mm to 1.6 mm, from 1.0 mm to 1.8 mm, from 1.0 mm to 2.0 mm, from 1.0 mm to 2.2 mm, from 1.0 mm to 2.4 mm, from 1.0 mm to 2.6 mm, from 1.0 mm to 2.8 mm, from 1.0 mm to 3.0 mm, from 1.0 mm to 3.2 mm, from 1.0 mm to 3.4 mm, from 1.0 mm to 3.6 mm, from 1.0 mm to 3.8 mm, from 1.0 mm to 4.0 mm, from 1.0 mm to 4.2 mm, from 1.0 mm to 4.4 mm, from 1.0 mm to 4.6 mm, from 1.0 mm to 4.8 mm, from 1.0 mm to 5.0 mm, from 3.0 mm to 3.2 mm, from 3.0 mm to 3.4 mm, from 3.0 mm to 3.6 mm, from 3.0 mm to 3.8 mm, from 3.0 mm to 4.0 mm, from 3.0 mm to 4.2 mm, from 3.0 mm to 4.4 mm, from 3.0 mm to 4.6 mm, from 3.0 mm to 4.8 mm, or even from 3.0 mm to 5.0 mm, or any and all endpoints formed by these subranges.

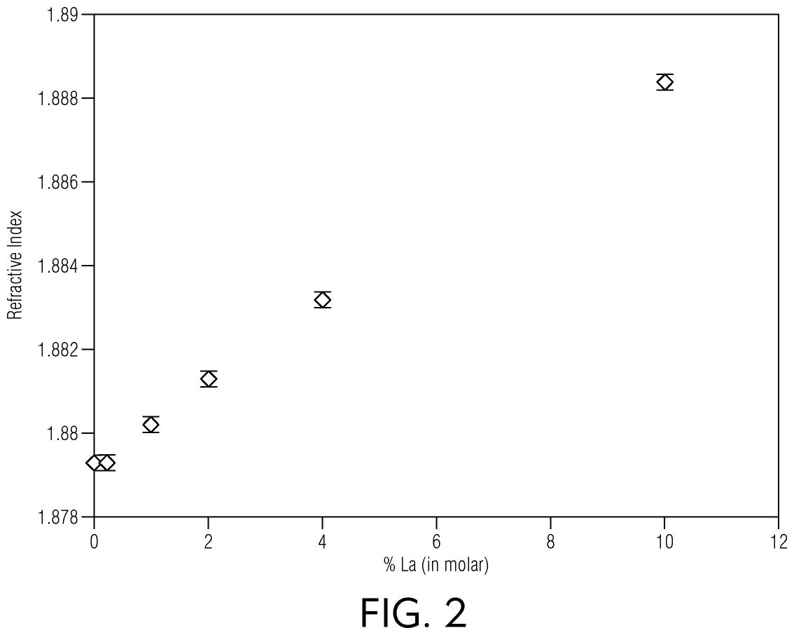

The axial optical transmission through the thickness of the polycrystalline ceramic substrate may be about 80% in the wavelength range of 1000-2000 nm, which is close to the theoretical limit of Y₂O₃ at 1535 nm (82.7%). The refractive index of transparent Y₂O₃ ceramics may be tuned by rare-earth doping, such as by erbium doping and/or erbium and lanthanum co-doping, as an example. As seen in FIG. 2, the refractive index of transparent erbium-Y₂O₃ ceramics increases as more lanthanum dopant is added. The transparent erbium-Y₂O₃ ceramic material included 20 ppm or erbium.

Referring again to FIG. 1, in embodiments, the rib waveguide 200 comprises a core 202 formed from silicon nitride (i.e., a silicon nitride core). In embodiments, the silicon nitride is stoichiometric silicon nitride (i.e., Si₃N₄). However, it should be understood that other stoichiometries of the silicon nitride are contemplated and possible and may be referred to generally as SiNₓ which is common nomenclature in the art. Accordingly, it should be understood that SiNₓ encompasses Si₃N₄ (i.e., where “x” is 1.33) as well as other species of silicon nitride.

As noted herein, the core 202 of the rib waveguide 200 has a core rib refractive index n_{CR}. In embodiments, the core rib refractive index n_{CR} is greater than or equal to 1.9 and less than or equal 2.1. For example, the core rib refractive index n_{CR} may be from 1.9 to 2.1, from 1.9 to 2.05, from 1.9 to 2.0, from 1.9 to 1.95, from 1.95 to 2.1, from 1.95 to 2.05, from 1.95 to 2.0, from 2.0 to 2.1, from 2.0 to 2.05, or even from 2.05 to 2.1, or any and all endpoints formed from these subranges.

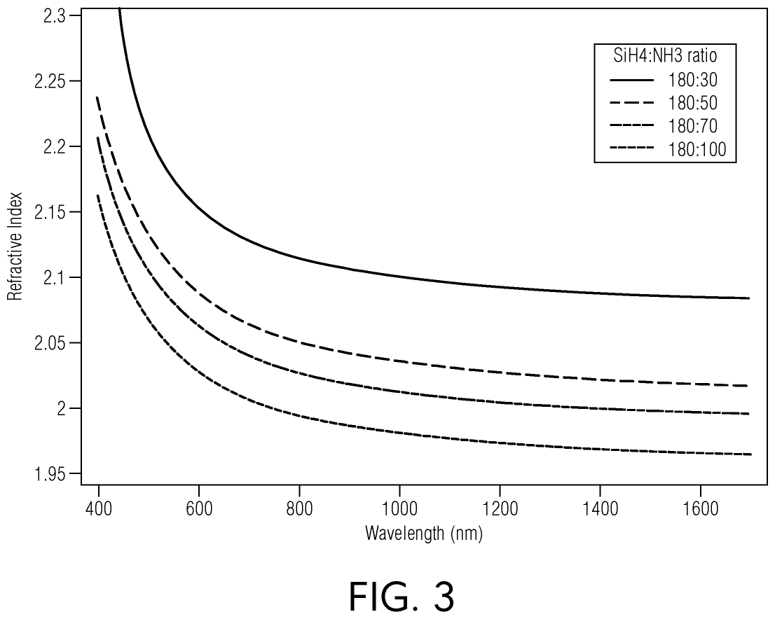

In embodiments, the core 202 is initially formed on the polycrystalline ceramic substrate 203 as a film. As an example, a 500 nm thick silicon nitride film may be deposited onto an erbium-Y₂O₃ substrate. The silicon nitride film may be deposited in a plasma-enhanced chemical vapor deposition (PECVD) chamber with different SiH₄:NH₃ ratios at 400° C. FIG. 3 shows the refractive index of a silicon nitride film as a function of wavelength with SiH₄:NH₃ ratios varied between 180:30 and 180:100. For example, in embodiments, the SiH₄:NH₃ ratio may be greater than or equal to 180:30, greater than or equal 180:40, greater than or equal to 180:50, or even greater than or equal to 180:60. The SiH₄:NH₃ ratio may be less than or equal to 180:100, less than or equal to 180:90, less than or equal to 180:80, or even less than or equal to 180:70. The SiH₄:NH₃ ratio may be from 180:30 to 180:100, from 180:30 to 180:90, from 180:30 to 180:80, from 180:30 to 180:70, from 180:30 to 180:60, from 180:30 to 180:50, from 180:30 to 180:40, from 180:40 to 180:100, from 180:40 to 180:90, from 180:40 to 180:80, from 180:40 to 180:70, from 180:40 to 180:60, from 180:40 to 180:50, from 180:50 to 180:100, from 180:50 to 180:90, from 180:50 to 180:80, from 180:50 to 180:70, from 180:50 to 180:60, from 180:60 to 180:100, from 180:60 to 180:90, from 180:60 to 180:80, from 180:80 to 180:100, from 180:80 to 180:90, or even from 180:90 to 180:100, or any and all endpoints formed by these subranges. As indicated in FIG. 3, varying the ratio of SiH₄:NH₃ during the deposition of the silicon nitride film may alter the refractive index of the silicon nitride film and also the stoichiometry of the deposited silicon nitride.

As seen in FIG. 3, the higher the ratio of SiH₄:NH₃, the higher the refractive index. Without being bound by any particular theory, it is believed that the refractive index increases proportionally to the silicon and nitrogen ratio in the film. Specifically, the refractive index increases proportionally with the refractive index of stoichiometric Si₃N₄ and silicon. In embodiments, a SiH₄:NH₃ ratio of 180:70 may be selected to achieve a silicon nitride refractive index equal to approximately 2. This refractive index may be tuned based on the core size and the index of the ceramic substrate. Therefore, it should be understood that other SiH₄:NH₃ ratios may be selected depending on the desired waveguide design.

Referring again to FIG. 1, in embodiments, the cladding layer 201 of the rib waveguide 200 may be formed from silica-based glass, such a pure silica glass (SiO₂) or SiO₂ doped with a dopant that increases or decreases the index of refraction of the SiO₂. An “up-dopant” is a substance added to the glass that has a propensity to raise the refractive index relative to pure undoped silica. Examples of up-dopants include GeO₂ (germania), Al₂O₃, P₂O₅, TiO₂, Cl, Br, and alkali metal oxides, such as K₂O, Na₂O, Li₂O, Cs₂O, Rb₂O, and mixtures thereof. A “down-dopant” is a substance added to the glass that has a propensity to lower the refractive index relative to pure undoped silica. Examples of down-dopants include fluorine and boron. In the embodiments described herein, the SiO₂ of the cladding layer 201 may include an up-dopant or a down-dopant to modify the index of refraction of the cladding layer 201 so long as the relationship n_{CR}>n_{S}>n_{Cl} is maintained.

In embodiments, the cladding refractive index n_{Cl} of the cladding layer 201 at 1550 nm may be greater than or equal to 1.40 and less than or equal to 1.50. In embodiments, the cladding refractive index n_{Cl} at 1550 nm is greater than or equal to 1.42 and less than or equal to 1.48, or even greater than or equal to 1.43 and less than or equal to 1.46.

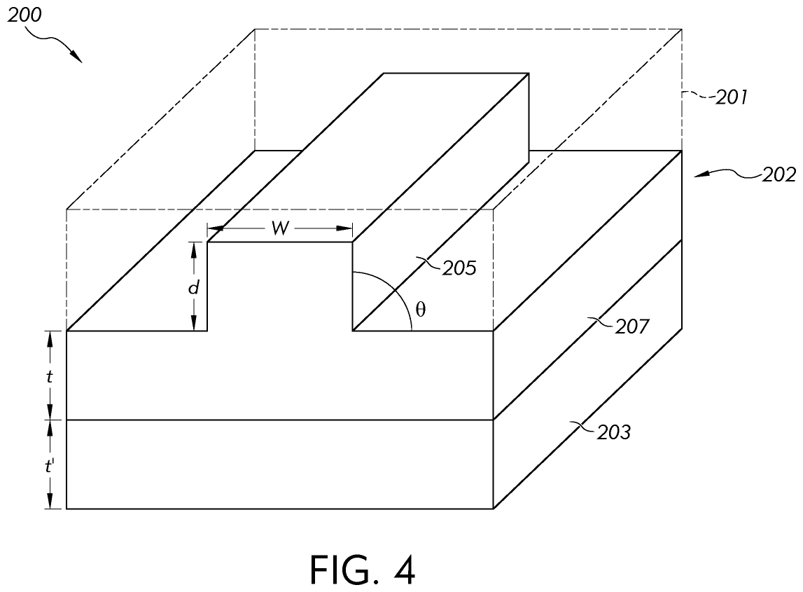

Referring now to FIG. 4, an isometric view of the rib waveguide 200 is depicted. As noted herein, the rib waveguide 200 comprises a polycrystalline ceramic substrate 203, a core 202, and a cladding layer 201, as described herein with respect to FIG. 1. As depicted in FIG. 4, the core 202 comprises a base 207 and a core rib 205 positioned on the base 207. The core rib 205 has a width w and a thickness d. The base 207 comprises a thickness t. In embodiments, core 202 has a taper angle θ between the core rib 205 and the base 207. The polycrystalline ceramic substrate 203 has a thickness t′.

In embodiments, the width w of the core rib 205 may be greater than or equal to 1 μm and less than or equal to 20 μm. In embodiments, the width of the core rib 205 may be greater than or equal to 1 μm, greater than or equal to 3 μm, greater than or equal to 5 μm, greater than or equal to 7 μm, or even greater than or equal to 9 μm. In embodiments, the width of the core rib 205 may be less than or equal to 20 μm, less than or equal to 18 μm, less than or equal to 16 μm, less than or equal to 14 μm, less than or equal to 12 μm, or even less than or equal to 10 μm. In embodiments, the width of the core rib 205 may be from 1 μm to 20 μm, from 1 μm to 18 μm, from 1 μm to 16 μm, from 1 μm to 14 μm, from 1 μm to 12 μm, from 1 μm to 10 μm, from 1 μm to 8 μm, from 1 μm to 6 μm, from 1 μm to 4 μm, from 1 μm to 2 μm, from 4 μm to 20 μm, from 4 μm to 18 μm, from 4 μm to 16 μm, from 4 μm to 14 μm, from 4 μm to 12 μm, from 4 μm to 10 μm, from 4 μm to 8 μm, from 4 μm to 6 μm, from 8 μm to 20 μm, from 8 μm to 18 μm, from 8 μm to 16 μm, from 8 μm to 14 μm, from 8 μm to 12 μm, from 8 μm to 10 μm, from 12 μm to 20 μm, from 12 μm to 18 μm, from 12 μm to 16 μm, from 12 μm to 14 μm, from 16 μm to 20 μm, or even from 16 μm to 18 μm, or any and all endpoints formed within these subranges.

In embodiments, the thickness d of the core rib 205 may be greater than or equal to 100 nm and less than or equal to 800 nm greater than or equal to 100 nm and less than or equal to 500 nm, or even greater than or equal to 150 nm and less than or equal to 250 nm.

In embodiments, the thickness t of the base 207 may be greater than or equal to 100 nm and less than or equal to 500 nm. In embodiments, the base 207 may have a thickness from greater than or equal to 100 nm, greater than or equal to 200 nm, or even greater than or equal to 300 nm. In embodiments, the base 207 may have a thickness from less than or equal to 500 nm, less than or equal to 400 nm, or even less than or equal to 300 nm. In embodiments, the base 207 may have a thickness of from 100 nm to 500 nm, from 100 nm to 400 nm, from 100 nm to 300 nm, from 100 nm to 200 nm, from 200 nm to 500 nm, from 200 nm to 400 nm, from 200 nm to 300 nm, from 300 nm to 500 nm, from 300 nm to 400 nm, or even from 400 nm to 500 nm, or any and all endpoints formed from these subranges.

In embodiments, the taper angle θ between the core rib 205 and the base 207 may be from 85.0° to 90.0°. For example, in embodiments, the taper angle θ may be greater than or equal to 85.0°, greater than or equal to 85.5°, greater than or equal to 86.0°, greater than or equal to 86.5°, greater than or equal to 87.0°, or even greater than or equal to 87.5°. In embodiments, the taper angle θ may be less than or equal to 90.0°, less than or equal to 89.5°, less than or equal to 89.0°, less than or equal to 88.5°, less than or equal to 88.0°, or even less than or equal to 87.5°. In embodiments, the taper angle θ may be from 85.0° to 90.0°, from 85.0° to 89.0°, from 85.0° to 88.0°, from 85.0° to 87.0°, from 85.0° to 86.0°, from 86.0° to 90.0°, from 86.0° to 89.0°, from 86.0° to 88.0°, from 86.0° to 87.0°, from 87.0° to 90.0°, from 87.0° to 89.0°, from 87.0° to 88.0°, from 88.0° to 90.0°, from 88.0° to 90.0°, from 88.0° to 89.0°, or even from 89.0° to 90.0°, or any and all endpoints formed within these subranges. A waveguide with a taper angle that is closer to 90° allows for less light to leak from the waveguide, thus better concentrating the light within the waveguide and the substrate.

In embodiments, the thickness t′ of the polycrystalline ceramic substrate 203 may be greater than or equal to 0.1 mm and less than or equal to 5 mm, greater than or equal to 0.5 mm and less than or equal to 3 mm, or even greater than or equal to 1 mm and less than or equal to 2 mm.

Silicon nitride is well-studied in both its deposition and etching characteristics. As such, the silicon nitride material, as deposited, may be readily manipulated, such as by etching, to control the taper angle and thereby obtain a smoother, more uniform sidewall in the core rib 205. Further, as noted herein, the optical properties of silicon nitride may be varied during deposition and subsequent annealing to achieve the desired optical characteristics, including the index of refraction of the silicon nitride.

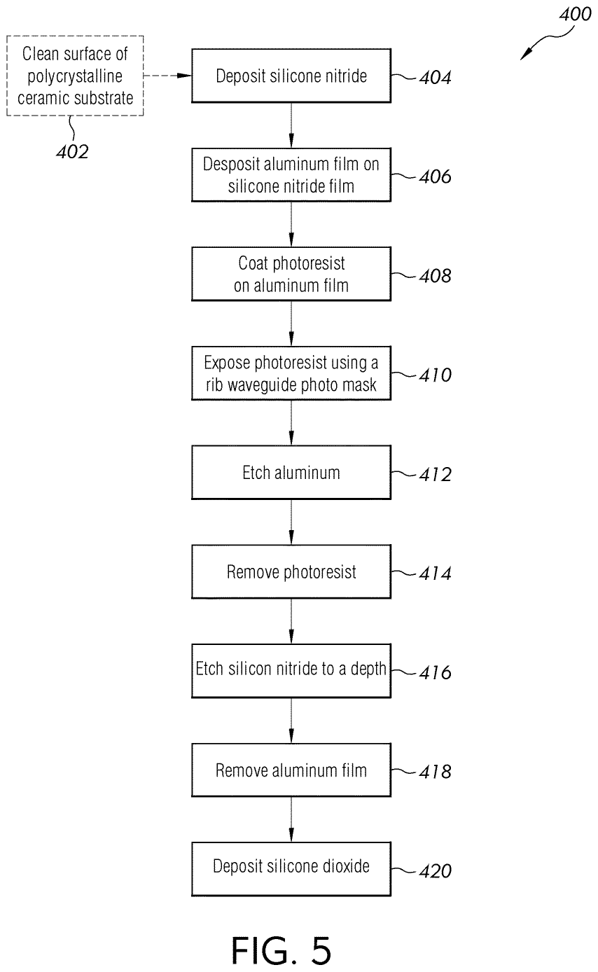

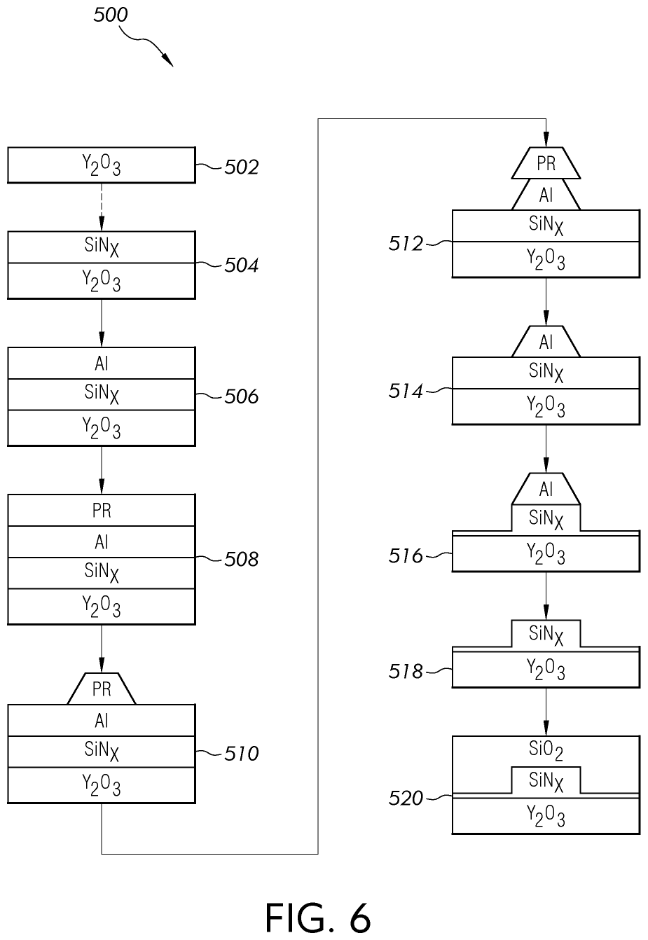

Referring now to FIGS. 5 and 6, FIG. 5 is a flow chart of a method of forming the rib waveguide 200 of FIGS. 1 and 4, while FIG. 6 schematically depicts the steps of forming the same.

As an optional initial step at blocks 402 and 502, the surface of a prepared polycrystalline ceramic substrate may be cleaned. The cleaning may be performed with acetone and/or isopropyl alcohol. The substrate may further undergo oxygen plasma cleaning. The polycrystalline ceramic substrate may be an erbium-Y₂O₃ transparent polycrystalline ceramic substrate as described herein with respect to FIGS. 1 and 2. The polycrystalline ceramic substrate may be further doped with one or more additional rare-earth dopants, such as lanthanum, to adjust the index of refraction of the substrate to a desired value.

At block 404 of FIG. 5 and block 504 of FIG. 6, a silicon nitride film is deposited on the polycrystalline ceramic substrate using PECVD to form the silicon nitride core. For example, a silicon nitride film may be deposited by PECVD with a SiH₄:NH₃ ratio of 180:70 at 400° C. on the polycrystalline ceramic substrate. The silicon nitride film may have a pre-etching thickness of from 300 nm to 600 nm. In embodiments, the silicon nitride film may have a pre-etching thickness from greater than or equal to 300 nm, greater than or equal to 350 nm, greater than or equal to 400 nm, or even greater than or equal 450 nm. In embodiments, the silicon nitride film may have a pre-etching thickness from less than or equal to 600 nm, less than or equal to 550 nm, less than or equal to 500 nm, or even less than or equal to 450 nm. In embodiments, the silicon nitride film may a pre-etching thickness of from 300 nm to 600 nm, from 300 nm to 550 nm, from 300 nm to 500 nm, from 300 nm to 450 nm, from 300 nm to 400 nm, from 300 nm to 350 nm, from 350 nm to 600 nm, from 350 nm to 550 nm, from 350 nm to 500 nm, from 350 nm to 450 nm, from 350 nm to 400 nm, from 400 to 600 nm, from 400 nm to 550 nm, from 400 nm to 500 nm, from 400 nm to 450 nm, from 450 nm to 600 nm, from 450 nm to 550 nm, from 450 nm to 500 nm, from 500 nm to 600 nm, from 500 nm to 550 nm, or even from 550 nm to 600 nm, or any and all endpoints formed from these subranges.

At block 406 of FIG. 5 and block 506 of FIG. 6, an aluminum film is deposited on the silicon nitride film by sputtering. For example, the aluminum film may be deposited by sputtering on the silicon nitride film. In embodiments, the aluminum film may have a pre-etching thickness of from 5 nm to 50 nm. In embodiments, the aluminum film may have a pre-etching thickness greater than or equal to 5 nm, 15 nm, 25 nm, or even 35 nm. In embodiments, the aluminum film may have a pre-etching thickness less than or equal to 50 nm, 40 nm, 30 nm, or even 20 nm. For example, in embodiments, the aluminum film may have a pre-etching thickness of from 5 nm to 50 nm, from 5 nm to 40 nm, from 5 nm to 30 nm, from 5 nm to 20 nm, from 5 nm to 10 nm, from 10 nm to 50 nm, from 10 nm to 40 nm, from 10 nm to 30 nm, from 10 nm to 20 nm, from 20 nm to 50 nm, from 20 nm to 40 nm, from 20 nm to 30 nm, from 30 nm to 50 nm, from 30 nm to 40 nm, or even from 40 nm to 50 nm, or any and all end points formed by these subranges.

At block 408 of FIG. 5 and block 508 of FIG. 6, a photoresist layer is coated on the aluminum film. For example, the photoresist layer may formed from a photoresist material such as SPR 220 3.0. The photoresist layer may be added in a 1:1 ratio with solvent.

At block 410 of FIG. 5 and block 510 of FIG. 6, the photoresist layer is exposed using photolithography and a designed photomask corresponding to a rib waveguide.

At block 412 of FIG. 5 and block 512 of FIG. 6, the aluminum layer is etched through using reactive ion etching (RIE). For example, the aluminum layer may be etched with an Oxford Plasmalab RIE system with mixed boron trichloride (BCl₃) gas at 10 standard cubic centimeters per minute (sccm), chlorine gas at 35 sccm, hydrogen at 10 sccm, and nitrogen at 4 sccm. The chamber pressure during the etching may be at 5 mTorr and the temperature may be at 60° C. Additionally, the RF power may be at 25 W, and the inductively coupled plasma (ICP) power may be at 400 W.

At block 414 of FIG. 5 and block 514 of FIG. 6, the photoresist layer is removed. For example, the photoresist layer may be removed by oxygen plasma cleaning in an Oxford Plasmalab RIE system.

At block 416 of FIG. 5 and block 516 of FIG. 6, the silicon nitride core is etched using RIE to a designed depth on the designed waveguide photomask. For example, the silicon nitride core may be etched from the silicon nitride film using an Oxford Plasmalab RIE system with mixed trifluoromethane (CHF₃) at 35 sccm, oxygen at 10 sccm, and sulfur tetrafluoride (SF₄) at 5 sccm. The chamber pressure during the etching may be at 3.8 mTorr and the temperature may be at 25° C. Additionally, the RF power may be at 50 W, and the inductively coupled plasma (ICP) power may be at 500 W.

At block 418 of FIG. 5 and block 518 of FIG. 6, the aluminum film is removed. For example, the aluminum film may be removed by RIE. For example, the aluminum layer may be removed with an Oxford Plasmalab RIE system with mixed boron trichloride (BCl₃) gas at 10 sccm, chlorine gas at 35 sccm, hydrogen at 10 sccm, and nitrogen at 4 sccm. The chamber pressure during the etching may be at 5 mTorr and the temperature may be at 60° C. Additionally, the RF power may be at 25 W, and the inductively coupled plasma (ICP) power may be at 400 W.

At block 420 of FIG. 5 and block 520 of FIG. 6, a cladding layer is coated onto the fabricated waveguide. For example, silica-based glass may be coated onto the fabricated waveguide to form a cladding layer. In embodiments, the cladding layer may have a thickness of from 1 μm to 5 μm. In embodiments, the cladding layer may be from 1 μm to 5 μm, from 1 μm to 4 μm, from 1 μm to 3 μm, from 1 μm to 2 μm, from 2 μm to 5 μm, from 2 μm to 4 μm, from 2 μm to 3 μm, from 3 μm to 5 μm, from 3 μm to 4 μm, or even from 4 μm to 5 μm, or any and all endpoints formed by these subranges.

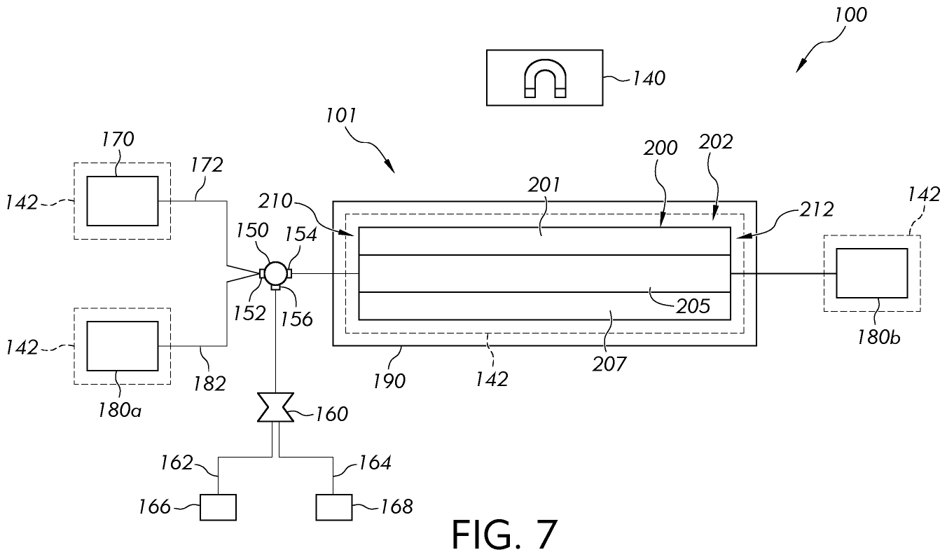

In embodiments, the rib waveguide 200 of FIGS. 1 and 4 may be used in quantum memory devices and systems. FIG. 7 is a schematic illustration of quantum memory system 100. The quantum memory system 100 comprises an optical device 101, a magnetic field generation unit 140, a storage photon generator 170, and one or more pump lasers 180, for example a first pump laser 180 a and a second pump laser 180 b. As described below, the quantum memory system 100 is structurally configured to store and release one or more storage photons, for example, on demand, such that the quantum memory system 100 may be synchronized with one or more additional quantum memory systems to form a quantum repeater system. Further, the components of the quantum memory system 100, for example, the optical device 101 may be positioned in an optical system that includes one or more quantum repeater systems each comprising optical devices 101. The optical system including the one or more quantum repeater systems may be structurally configured to entangle a pair of storage photons that are each stored and released by the optical devices 101 of the respective quantum memory systems. Moreover, the quantum memory system 100 and the optical system described herein may be incorporated into one or more quantum communications systems, for example, quantum key generation systems, quantum telecommunications systems, quantum internet systems, and any other current or yet-to be developed quantum communications systems.

As depicted in FIG. 7, the optical device 101 may comprise a rib waveguide 200 having a polycrystalline ceramic substrate (not depicted), a core 202 formed from silicon nitride (i.e., a silicon nitride core) and a cladding 201 surrounding the core 202.

The rib waveguide 200 of the optical device 101 may be as described herein with respect to FIGS. 1-6. For example, the core 202 may be formed from silicon nitride, the substrate of the rib waveguide 200 may comprise a erbium-doped yttrium oxide, and the cladding may comprise silica-based glass. Referring again to FIG. 7, the storage photon generator 170 is optically coupled to the core 202 of the rib waveguide 200 of the optical device 101, for example, to a first end 210 or a second end 212 of the optical device 101, and is structurally configured to generate and emit a storage photon, for example, an entangled storage photon or a non-entangled storage photon. The storage photon generator 170 comprises a photon source, for example, a laser, a laser optically coupled to a non-linear crystal, a parametric down convertor, or the like. Further, the storage photon generator 170 may generate and emit storage photons using a four-wave mixing process, or any method or process of generating photons.

In operation, the storage photon generator 170 may generate and emit storage photons having any wavelength, for example, between about 300 nm and about 10 μm, for example, 500 nm, 1550 nm, 2200 nm, or the like. As a non-limiting example, the storage photon emitted by the storage photon generator 170 may comprise a first entangled storage photon that is entangled with a second entangled storage photon simultaneously emitted by the storage photon generator 170. In operation, the first entangled storage photon may traverse the rib waveguide 200 of the optical device 101 and the second entangled storage photon may travel along a pathway separate from the optical device 101 while remaining entangled with the first entangled storage photon.

Referring still to FIG. 7, the storage photon generator 170 may be optically coupled to the core 202 of the rib waveguide 200 of the optical device 101 using a storage photon transmission fiber 172 or other waveguide device, which may extend between the storage photon generator 170 and the first or second end 210, 212 of the optical device 101. Further, the storage photon generator 170 may be optically coupled to the first or second end 210, 212 of the optical device 101 by aligning the storage photon generator 170 with the first end 210 or the second end 212, for example, using one or more alignment mechanisms 142 structurally configured to optically align the storage photon generator 170 with the core 202 of the rib waveguide 200 of the optical device 101. The one or more alignment mechanisms 142 may comprise an alignment stage, an optical switch, or both. Further, the storage photon generator 170 and/or the optical device 101 may be coupled to individual alignment mechanisms 142.

The one or more pump lasers 180 are optically coupled to the core 202 of the rib waveguide 200 of the optical device 101 and are each structurally configured to generate and emit pump pulses. The one or more pump lasers 180 may comprise any laser source, for example, a diode laser, an external cavity diode laser, a fiber laser, a dye laser, or the like. Further, the one or more pump lasers 180 may be structurally configured to emit pump pulses having any wavelength, for example, between about 500 nm and about 2200 nm. Moreover, the wavelength of the pump pulses generated and emitted by the one or more pump lasers 180 may be larger than the wavelength of the storage photons generated and emitted by the storage photon generator 170.

Further, as depicted in FIG. 7, the one or more pump lasers 180 may comprise a first pump laser 180 a and a second pump laser 180 b. For example, the first pump laser 180 a may be optically coupled to the core 202 of the rib waveguide 200 at the first end 210 of the optical device 101 and the second pump laser 180 b may be optically coupled to the core 202 of the rib waveguide 200 at the second end 212 of the optical device 101. As depicted in FIG. 1, the first pump laser 180a may be optically coupled to the same end of the optical device 101 as the storage photon generator 170 (e.g., the first end 210) and the second pump laser 180 b may be optically coupled to a different end of the optical device 101 as the storage photon generator 170 (e.g., the second end 212). Optically coupling the first and second pump lasers 180 a. 180 b to different ends of the optical device 101 may decrease optical scattering within the optical device 101 of the storage photon during operation of the quantum memory system 100 As depicted in FIG. 7, each pump laser 180 may be optically coupled to the core 202 of the rib waveguide 200 of the optical device 101 using a pump pulse transmission fiber 182 or other waveguide device, which may extend between each pump laser 180 and the optical device 101. Further, each pump laser 180 may be optically coupled to the core 202 of the rib waveguide 200 of the optical device 101 using one or more alignment mechanisms 142 structurally configured to optically align each pump laser 180 with the core 202 of the rib waveguide 200 of the optical device 101. Further, the one or more pump lasers 180 and/or the optical device 101 may be coupled to individual alignment mechanisms 142.

Still to FIG. 7, the quantum memory system 100 may further comprise a wavelength division multiplexer (WDM) 160 optically coupled to the core 202 of the rib waveguide 200 of the optical device 101. In particular, the WDM 160 is optically coupled to the end of the optical device 101 where the storage photon exits the optical device 101. For example, as depicted in FIG. 1, the WDM 160 may be optically coupled to the core 202 of the rib waveguide 200 at the first end 210 of the optical device 101. Further, the WDM 160 may be optically coupled to both a storage photon pathway 162 and a pump pulse pathway 164, for example, the WDM 160 may be positioned between an end (e.g., the first end 210) of the optical device 101 and both the storage photon pathway 162 and the pump pulse pathway 164. The WDM 160 is configured to direct the storage photons into the storage photon pathway 162 and direct the pump pulses into the pump pulse pathway 164. For example, the WDM 160 may direct a wavelength range of photons encompassing the wavelengths of the storage photons into the storage photon pathway 162 and may direct a wavelength range of photons encompassing the wavelengths of the pump pulses into the pump pulse pathway 164. Further, the storage photon pathway 162 and the pump pulse pathway 164 may comprise optical fibers.

The storage photon pathway 162 may extend between the WDM 160 and a storage photon receiver 166. Further, the pump pulse pathway 164 may extend between the WDM 160 and a pump pulse receiver 168. In operation, the first and second pump pulses may terminate at the pump pulse receiver 168, for example, the pump pulse receiver 168 may comprise a fiber end in embodiments in which the pump pulse pathway 164 comprises an optical fiber.

Referring still to FIG. 7, the quantum memory system 100 may further comprise an optical circulator 150 optically coupled the core 202 of the rib waveguide 200 of the optical device 101, for example, at the first end 210 of the optical device 101. The optical circulator 150 comprises three or more optical ports, for example, a first optical port 152, a second optical port 154, and a third optical port 156. Further, the optical circulator 150 is positioned between the storage photon generator 170 and the optical device 101, for example, the first end 210 of the optical device 101 such that a first optical port 152 of the optical circulator 150 is optically coupled to the storage photon generator 170 and the second port is optically coupled to the first end 210 of the optical device 101.

The optical circulator 150 may also be positioned between at least one of the pump lasers 180 (e.g., the first pump laser 180 a) and the first end 210 of the optical device 101 such that the first optical port 152 of the optical circulator 150 is optically coupled to at least one of the one or more pump lasers 180 and the second optical port 154 is optically coupled to the first end 210 of the optical device 101. For example, as depicted in FIG. 7, the storage photon generator 170 and the first pump laser 180a are each optically coupled to the first optical port 152 of the optical circulator 150 such that storage photons output by the storage photon generator 170 and the first pump pulse output by the first pump laser 180 a enter the first optical port 152 of the optical circulator 150 and exit the second optical port 154 towards the first end 210 of the optical device 101.

The optical circulator 150 may also be positioned between the WDM 160 and the optical device 101, for example, the first end 210 of the rib waveguide 200. Further, the third optical port 156 of the optical circulator 150 is optically coupled to the WDM 160. For example, the WDM 160 is positioned adjacent and optically coupled to the third optical port 156 of the optical circulator 150 such that the WDM 160 receives the storage photon after the storage photon exits the first end 210 of the optical device 101 and may receive one or both of the pump pulses output by the first and second pump lasers 180 a, 180 b.

As depicted in FIG. 7, the quantum memory system 100 may further comprise a cooling system 190 thermally coupled to the optical device 101. As a non-limiting example, the cooling system 190 may comprise a cooling chamber and the optical device 101 may be positioned within the cooling chamber. As another non-limiting example, the cooling system 190 may comprise a laser cooling system and the optical device 101 may be optically coupled to the laser cooling system. It should be understood that any cooling system 190 structurally configured to cool the optical device 101 is contemplated.

Referring still to FIG. 7, the magnetic field generation unit 140 may comprise any magnetic device structurally and compositionally configured to generate a magnetic field, for example, a static magnetic field. As non-limiting examples, the magnetic field generation unit 140 may comprise an electromagnet, a ferromagnet, an alcnico magnet, a samarium cobalt (SmCo) magnet, a neodymium iron boron (NdFeB) magnet, or combinations thereof. Further, the magnetic field generation unit 140 is positioned within the quantum memory system 100 such that, when the magnetic field generation unit 140 generates a magnetic field, the optical device 101 is positioned within the magnetic field of the magnetic field generation unit 140. For example, the magnetic field generation unit 140 may be adjacent the optical device 101. As a non-limiting example, the magnetic field generation unit 140 may be structurally and compositionally configured to generate a magnetic field comprising a magnetic flux density of between about 0.2 tesla and about 5 tesla. For example, the magnetic flux density from the magnetic field generation unit 140 may be from 0.2 tesla to 5 tesla, from 0.2 tesla to 4 tesla, from 0.2 tesla to 3 tesla, from 0.2 tesla to 2 tesla, from 0.2 tesla to 1 tesla, from 1 tesla to 5 tesla, from 1 tesla to 4 tesla, from 1 tesla to 3 tesla, from 1 tesla to 2 tesla, from 2 tesla to 5 tesla, from 2 tesla to 4 tesla, from 2 tesla to 3 tesla, from 3 tesla to 5 tesla, from 3 tesla to 4 tesla, or even from 4 tesla to 5 tesla, or any and all endpoints formed by these subranges.

Further, the optical device 101 may comprise a variety of shapes and sizes to facilitate photon absorption and release. For example, in embodiments, the optical device 101 may comprise a length extending between the first end 210 and the second end 212 that is between about 1 cm and about 50 cm, for example, 5 cm, 10 cm, 15 cm, 20 cm, 30 cm, 40 cm, or the like. For example, in embodiments, the length extending between the first end 210 and the second end 212 may be from 1 cm to 50 cm, from 1 cm to 45 cm, from 1 cm to 40 cm, from 1 cm to 35 cm, from 1 cm to 30 cm, from 1 cm to 25 cm, from 1 cm to 20 cm, from 1 cm to 15 cm, from 1 cm to 10 cm, from 1 cm to 5 cm, from 5 cm to 50 cm, from 5 cm to 45 cm, from 5 cm to 40 cm, from 5 cm to 35 cm, from 5 cm to 30 cm, from 5 cm to 25 cm, from 5 cm to 20 cm, from 5 cm to 15 cm, from 5 cm to 10 cm, from 10 cm to 50 cm, 10 cm to 45 cm, from 10 cm to 40 cm, from 10 cm to 35 cm, from 10 cm to 30 cm, from 10 cm to 25 cm, from 10 cm to 20 cm, from 10 cm to 15 cm, from 15 cm to 50 cm, from 15 to 45 cm, from 15 cm to 40 cm, from 15 cm to 35 cm, from 15 cm to 30 cm, from 15 cm to 25 cm, from 15 cm to 20 cm, from 20 cm to 50 cm, from 20 cm to 45 cm, from 20 cm to 40 cm, from 20 cm to 35 cm, from 20 cm to 30 cm, from 20 to 25 cm, from 25 cm to 50 cm, from 25 cm to 45 cm, from 25 cm to 40 cm, from 25 cm to 35 cm, from 25 cm to 30 cm, from 30 cm to 50 cm, from 30 cm to 45 cm, from 30 cm to 40 cm, from 30 cm to 35 cm, from 35 cm to 50 cm, from 35 cm to 45 cm, from 35 cm to 40 cm, from 40 cm to 50 cm, from 40 cm to 45 cm, or even from 45 cm to 50 cm, or any and all endpoints formed by these subranges.

Further, in embodiments, the rib waveguide 200 may comprise a cross sectional area (i.e., the cross-section depicted in FIG. 1) of between about 0.0001 mm² and about 25 mm², for example, about 0.0001 mm², 0.0005 mm², 0.001 mm², 0.005 mm², 0.01 mm², 0.05 mm², 0.1 mm², 0.5 mm², 1 mm², 2 mm², 5 mm², 10 mm², 15 mm², 20 mm², or the like. For example, the cross-sectional area may be from 0.0001 mm² to 25 mm², from 0.0001 mm² to 20 mm², from 0.0001 mm² to 15 mm², from 0.0001 mm² to 10 mm², from 0.0001 mm² to 5 mm², from 0.0001 mm² to 1 mm², from 0.0001 mm² to 0.001 mm² , from 0.001 mm² to 25 mm², from 0.001 mm² to 20 mm², from 0.001 mm² to 15 mm², from 0.001 mm² to 10 mm², from 0.001 mm² to 5 mm², from 0.001 mm² to 1 mm², from 1 mm² to 25 mm², from 1 mm² to 20 mm², from 1 mm² to 15 mm², from 1 mm² to 10 mm², from 1 mm² to 5 mm², from 5 mm² to 25 mm², from 5 mm² to 20 mm², from 5 mm² to 15 mm², from 5 mm² to 10 mm², from 10 mm² to 25 mm², from 10 mm² to 20 mm², from 10 mm² to 15 mm², from 15 mm² to 25 mm², from 15 mm² to 20mm², or even from 20 mm² to 25 mm², or any and all endpoints formed by these subranges.

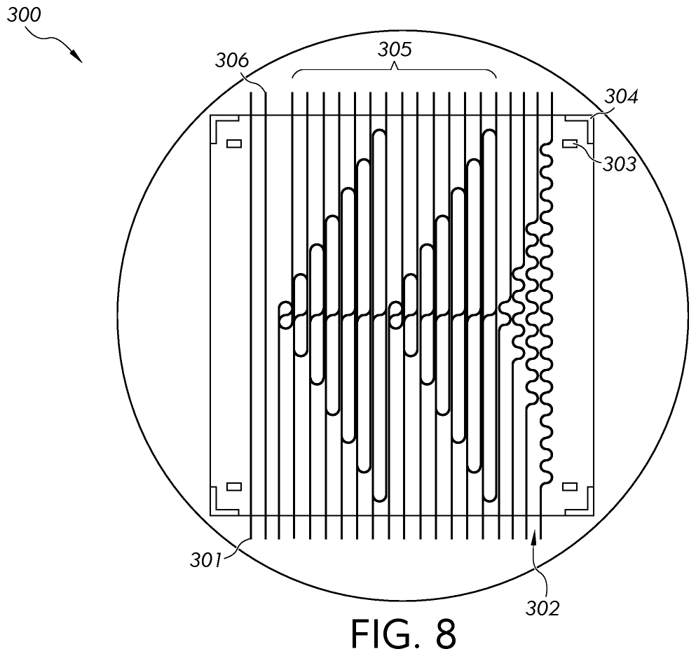

Referring now to FIG. 8, an embodiment of a waveguide design employed within a quantum memory device 300 is depicted. There are a different total number of lengths 305 depicted in FIG. 3, in addition to a different number of bends 302. Different tapers are shown as well. For example, a straight waveguide with no taper 301 is depicted in addition to a straight waveguide with a 200 μm taper 306. Finally, for manufacturing purposes, polishing stop marks 304 and alignment marks 303 are shown.

### Examples

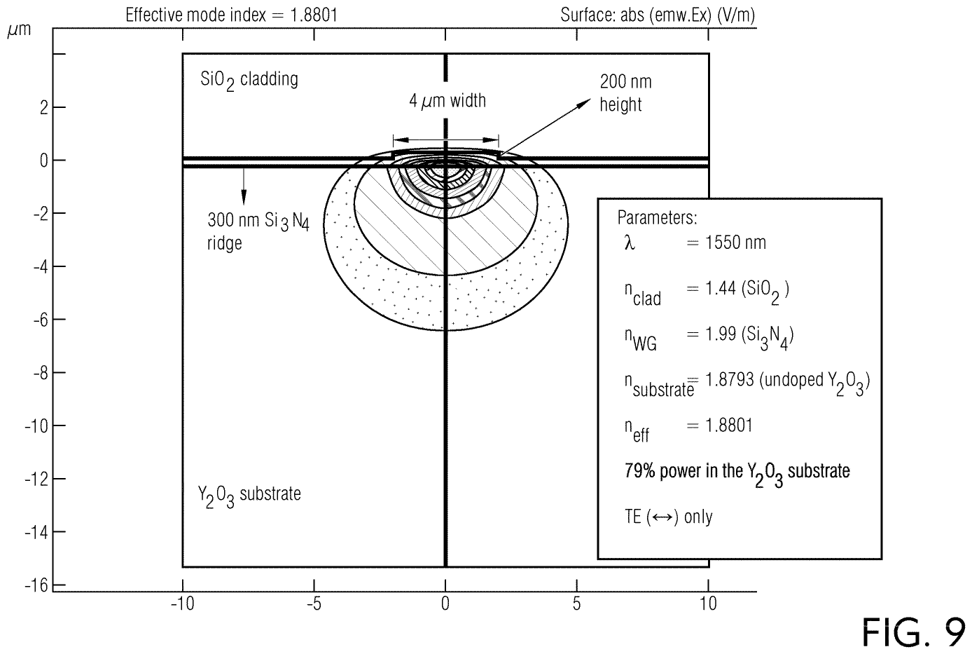

Referring now to FIG. 9, a rib waveguide having the design of FIG. 4 was simulated using COMSOL Multiphysics® software. In this simulation, the silicon nitride (Si₃N₄) forming the core (i.e., the core rib 205 and the base 207) was simulated with a refractive index equal to 1.99. The wavelength of the light introduced to the core of the rib waveguide in the simulation depicted in FIG. 9 was 1550 nm. The cladding was simulated as pure SiO₂ with a refractive index of 1.44. The refractive index of the substrate was simulated as 1.8793 (only erbium-doped Y₂O₃ (erbium concentration of 20 ppm)). The effective refractive index of the waveguide was 1.8801.

The simulation demonstrates the waveguide's ability to confine light propagating in the waveguide to certain portions of the waveguide. In particular, FIG. 9 graphically demonstrates that, in this simulation, the waveguide structure confines the light in the rib waveguide to the silicon nitride core and the polycrystalline Y₂O₃ ceramic substrate. Specifically, the waveguide confined 79% of the light in the erbium-doped polycrystalline Y₂O₃ ceramic substrate.

It should now be understood that silicon nitride core rib waveguides according to the present disclosure include a rare-earth doped polycrystalline ceramic substrate, a silicon nitride core, and a cladding.

A method of fabricating a ceramic waveguide includes: depositing a silicon nitride film on a rare-earth doped transparent polycrystalline ceramic substrate; depositing an aluminum film on the silicon nitride film; coating a photoresist on the aluminum film; exposing the photoresist using a rib waveguide photo mask; etching the aluminum film; removing the photoresist; etching the silicon nitride film to a depth; removing the aluminum film; and depositing a silicon dioxide (SiO₂) cladding on to the silicon nitride film and the rare-earth doped transparent polycrystalline ceramic substrate.

The terms recited in the claims should be given their ordinary and customary meaning as determined by reference to relevant entries in widely used general dictionaries and/or relevant technical dictionaries, commonly understood meanings by those in the art, etc., with the understanding that the broadest meaning imparted by any one or combination of these sources should be given to the claim terms (e.g., two or more relevant dictionary entries should be combined to provide the broadest meaning of the combination of entries, etc.) subject only to the following exceptions: (a) if a term is used in a manner that is more expansive than its ordinary and customary meaning, the term should be given its ordinary and customary meaning plus the additional expansive meaning, or (b) if a term has been explicitly defined to have a different meaning by reciting the term followed by the phrase “as used in this document shall mean” or similar language (e.g., “this term means,” “this term is defined as,” “for the purposes of this disclosure this term shall mean,” etc.). References to specific examples, use of “i.e.,” use of the word “invention,” etc., are not meant to invoke exception (b) or otherwise restrict the scope of the recited claim terms. Other than situations where exception (b) applies, nothing contained in this document should be considered a disclaimer or disavowal of claim scope.

The subject matter recited in the claims is not coextensive with and should not be interpreted to be coextensive with any embodiment, feature, or combination of features described or illustrated in this document. This is true even if only a single embodiment of the feature or combination of features is illustrated and described in this document.

It will be apparent to those skilled in the art that various modifications and variations can be made without departing from the spirit or scope of the claimed subject matter. Accordingly, the claimed subject matter is not to be restricted except in light of the attached claims and their equivalents.

What is claimed is:

1. A method of fabricating a rib waveguide, the method comprising:
depositing a silicon nitride film on a rare-earth doped transparent polycrystalline ceramic substrate;
depositing an aluminum film on the silicon nitride film;
coating a photoresist on the aluminum film;
exposing the photoresist using a rib waveguide photo mask;
etching the aluminum film;
removing the photoresist;
etching the silicon nitride film to a depth;
removing the aluminum film; and
depositing a silicon dioxide (SiO2) cladding on to the silicon nitride film and the rare-earth doped transparent polycrystalline ceramic substrate.

2. The method of claim 1, wherein the rare-earth doped transparent polycrystalline ceramic substrate comprises yttrium oxide and an erbium dopant, or yttrium oxide and the erbium dopant mixed with one or a combination of the following dopants: lanthanum, scandium, and/or lutetium.

3. The method of claim 1, further comprising an initial step of cleaning the rare-earth doped transparent polycrystalline ceramic substrate, wherein the initial step of cleaning comprises applying at least one of acetone, isopropyl alcohol, and oxygen (O₂) plasma.

4. The method of claim 1, wherein the silicon nitride film has a pre-etching thickness from greater than or equal to 300 nm to less than or equal to 600 nm.

5. The method of claim 1, wherein the aluminum film has a pre-etching thickness from greater than or equal to 5 nm to less than or equal to 50 nm.

6. The method of claim 1, wherein the photoresist is removed by O2 plasma.

7. The method of claim 1, wherein the silicon nitride film is etched from 150 nm to 300 nm, forming the rib waveguide comprising
a silicon nitride base having a thickness from 100 nm to 500 nm; and
a silicon nitride core rib having a width from 1 μm to 20 μm and a taper angle from 85° to 90°.

8. The method of claim 1, wherein the aluminum film is removed by reactive ion etching.

9. The method of claim 1, wherein the SiO₂ cladding has a thickness from greater than or equal to 1 μm to less than or equal to 5 μm.

10. A rib waveguide, comprising:
a rare-earth doped transparent polycrystalline ceramic substrate having a substrate refractive ns;
a silicon nitride core disposed on the rare-earth doped transparent polycrystalline ceramic substrate, the silicon nitride core having a core rib refractive index n_{CR}, and
a cladding layer disposed on the silicon nitride core and the rare-earth doped transparent polycrystalline ceramic substrate, the cladding layer having a cladding refractive index n_{Cl}, wherein n_{CR}>n_{S}>n_{CL}.

11. The rib waveguide of claim 10, wherein the rare-earth doped transparent polycrystalline ceramic substrate comprises yttrium oxide.

12. The rib waveguide of claim 11, wherein the rare-earth doped transparent polycrystalline ceramic substrate comprises an erbium dopant, or the erbium dopant mixed with one or a combination of the following dopants: lanthanum, scandium, and/or lutetium.

13. The rib waveguide of claim 10, wherein the silicon nitride core comprises:
a silicon nitride base having a thickness from 100 nm to 500 nm; and
a silicon nitride core rib having a width from 1 μm to 20 μm and a taper angle from 85° to 90°.

14. The rib waveguide of claim 10, wherein the n_{CR} may be greater than or equal to 1.9 and less than or equal to 2.1.

15. The rib waveguide of claim 10, wherein the cladding layer comprises silica-based glass.

16. A quantum memory system comprising an optical device comprising a silicon nitride core on a rare-earth doped polycrystalline ceramic substrate, a magnetic field generation unit, a storage photon generator, and one or more pump lasers, wherein:
the optical device is positioned within a magnetic field of the magnetic field generation unit when the magnetic field generation unit generates the magnetic field;
the one or more pump lasers are optically coupled to the optical device;
the storage photon generator is optically coupled to the optical device and is structurally configured to output an entangled pair of storage photons comprising a first entangled storage photon entangled with a second entangled storage photon; and
the optical device further comprises a cladding surrounding the silicon nitride core.

17. The quantum memory system of claim 16, wherein the rare-earth doped polycrystalline ceramic substrate comprises yttrium oxide.

18. The quantum memory system of claim 16, wherein the rare-earth element comprises an erbium dopant, or the erbium dopant in combination with one or more of the following dopants:
lanthanum, scandium, and/or lutetium.

19. The quantum memory system of claim 16, wherein the cladding surrounding the silicon nitride core comprises silica-based glass.

20. The quantum memory system of claim 16, wherein the silicon nitride core comprises:
a silicon nitride base having a thickness from 100 nm to 300 nm; and
a silicon nitride core rib having a width from 1 μm to 20 μm and a taper angle from 85° to 90°.
